(19) United States
(12) Patent Application Publication
(10) Pub. No.: US 2026/0150661 A1
(43) Pub. Date: May 28, 2026

(54) INDUCTOR-CAPACITOR (L-C) CIRCUIT

(71) Applicant: International Business Machines Corporation, Armonk, NY (US)

(72) Inventors: Nicholas Alexander POLOMOFF, Hopewell Junction, NY (US); Kishan Jayanand, COHOES, NY (US); Chih-Chao Yang, Glenmont, NY (US); Ruilong Xie, Niskayuna, NY (US)

(21) Appl. No.: 18/958,643

(22) Filed: Nov. 25, 2024

(51) Int. Cl. H01L 23/522; H01F 17/00; H01L 23/528

(52) U.S. Cl. CPC H10W 20/496; H01F 17/0013; H10W 20/42; H10W 20/427; H10W 20/497; H01F 2017/0073

(57) ABSTRACT

A semiconductor device is provided that includes an inductor-capacitor (L-C) circuit in which the capacitor and inductor elements of the L-C circuit are located at a front-end-of-the-line (FEOL) level, and in which a first L-C wiring portion of the L-C circuit is present in a frontside back-end-of-the-line (BEOL) structure and a second L-C wiring portion of the L-C circuit is present in a backside BEOL structure.

### BACKGROUND

The present application relates to semiconductor technology, and more particularly to a semiconductor device including an inductor-capacitor (L-C) circuit in which a first LC-wiring portion of the L-C circuit is present in a frontside back-end-of-the-line (BEOL) structure and a second L-C wiring portion of the L-C circuit is present in a backside BEOL structure.

An L-C circuit, consisting of an inductor (L) and a capacitor (C) connected together, can oscillate, i.e., it can exchange energy between magnetic fields in the inductor and electric fields in the capacitor. L-C circuits have frequency variability and sensing capabilities. The frequency variability, i.e., shifts, are caused by change in capacitance in response to alterations in the environment. Deviations from resonant frequency values can be decoded as indicative signal, providing insights into parameter changes or potential anomalies. Frequency variations facilitate early detection of potential issues or material degradation allowing for preventative actions. Continuous frequency monitoring and data interpretation can enhance the reliability and operational lifetime of semiconductor devices by enabling timely interventions. In essence, by observing shifts in the resonant frequency of the L-C circuit, the system can transmit vital data about physical parameters and potential failure modes, ensuring stable and sustained operation of the semiconductor device.

### SUMMARY

A semiconductor device is provided that includes an L-C circuit in which the capacitor and inductor elements of the L-C circuit are located at a front-end-of-the-line (FEOL) level, and in which a first L-C wiring portion of the L-C circuit is present in a frontside BEOL structure and a second L-C wiring portion of the L-C circuit is present in a backside BEOL structure.

In one embodiment, a semiconductor device is provided that includes a FEOL level having a frontside BEOL structure located on a frontside side of the FEOL level and a backside BEOL structure located on a backside of the FEOL level; and an inductor-capacitor (L-C) circuit. The L-C circuit includes a first inductor, a second inductor and a capacitor present at the FEOL level, a first L-C circuit wiring portion located in the frontside BEOL structure, and a second L-C circuit wiring portion located in the backside BEOL structure. In accordance with the present application, the first L-C circuit wiring portion and the second L-C circuit wiring portion are interconnected to each other at, and through, the FEOL level.

In another embodiment, a semiconductor device is provided that includes a FEOL level having a frontside BEOL structure located on a frontside side of the FEOL level and a backside BEOL structure located on a backside of the FEOL level; and a monitor system configured to detect environmental and detect failure modes at the FEOL level. The monitor system includes a first inductor, a second inductor and a capacitor present at the FEOL level, a first L-C circuit wiring portion located in the frontside BEOL structure, and a second L-C circuit wiring portion located in the backside BEOL structure. In accordance with the present application, the first L-C circuit wiring portion and the second L-C circuit wiring portion are interconnected to each other at, and through, the FEOL level.

### BRIEF DESCRIPTION OF THE DRAWINGS

FIG. 1 is a cross sectional view of an exemplary semiconductor device in accordance with an embodiment of the present application.

FIG. 2 is a top down view highlighting an inductor device area of the exemplary semiconductor device illustrated in FIG. 1 including a first inductor and a second inductor.

FIG. 3 is a top down view highlighting a capacitor device area of the exemplary semiconductor device illustrated in FIG. 1 including a capacitor, C.

FIG. 4A-4E show various inductor shapes (from a top down view) that can be employed as the first inductor and second inductor illustrated in the exemplary semiconductor device shown in FIG. 1.

FIG. 5 is a three-dimensional (3D) illustration of a portion of the exemplary semiconductor device illustrated in FIG. 1.

FIG. 6 is another 3D illustration of a portion of the exemplary semiconductor device illustrated in FIG. 1.

FIG. 7 is a top down view highlighting the capacitor device area and the inductor device area of the exemplary semiconductor device illustrated in FIG. 1.

FIG. 8 is a cross sectional view of an initial structure that can be used in providing the exemplary semiconductor device illustrated in FIG. 1, the initial structure including a material stack of alternating layers of sacrificial semiconductor material layers and semiconductor channel material layers located on a surface of a substrate.

FIG. 9 is a cross sectional view of the initial structure illustrated in FIG. 8 after forming a pair of openings into a semiconductor device layer of the substrate, and filling the pair of openings with a capacitor dielectric layer.

FIG. 10 is a cross sectional view of the structure illustrated in FIG. 9 after forming a first capacitor plate on the capacitor dielectric layer in one of the openings of the pair of openings, and a first inductor on the capacitor dielectric layer in the other of the openings of the pair of openings.

FIG. 11 is a cross sectional view of the structure illustrated in FIG. 10 after forming a FEOL level.

FIG. 12 is a cross sectional view of the structure illustrated in FIG. 11 after forming a first frontside interlayer dielectric (ILD) layer, and forming a power via structure in the first frontside ILD layer and within a portion of the FEOL level that is located between the pair of openings.

FIG. 13 is a cross sectional view of the structure illustrated in FIG. 12 after forming a second frontside ILD layer, and frontside device contact via structures and a frontside power via contact via structure.

FIG. 14 is a cross sectional view of the structure illustrated in FIG. 13 after forming additional frontside ILD layers having metal vias, first level frontside metal lines, frontside interconnect metal via structures and second level frontside metal lines embedded therein.

FIG. 15 is a cross sectional view of the structure illustrated in FIG. 14 after bonding a topmost additional frontside ILD layer to a carrier wafer.

FIG. 16 is a cross sectional view of the structure illustrated in FIG. 15 after flipping the structure 180° to physically expose a semiconductor base layer of the substrate.

FIG. 17 is a cross sectional view of the structure illustrated in FIG. 16 after removing the semiconductor base layer and an etch stop layer of the substrate.

FIG. 18 is a cross sectional view of the structure illustrated in FIG. 17 after physically exposing the capacitor dielectric layer present in the pair of openings, forming a second capacitor plate on the capacitor dielectric layer in one of the openings of the pair of openings, and a second inductor on the capacitor dielectric layer in the other of the openings of the pair of openings, and forming a first backside ILD layer.

FIG. 19 is a cross sectional view of the structure illustrated in FIG. 18 after forming backside device contact via structures and a backside power via contact structure in the first backside ILD layer.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Throughout the present application, the term “inductor” denotes a passive electrical component that consists of electrically conductive wires that are wound up in a coil. An inductor is designed to take advantage of the relationship between magnetism and electricity. Notably, and when current flows through the inductor, a magnetic flux develops around it. This magnetic flux is proportional to the current flowing through it. The inductor opposes changes in the current flow (both in magnitude and direction), and it resists rapid changes in the current due to the build-up of self-induced energy within its magnetic field. In other words, an inductor stores energy in its magnetic field when current flows through it.

Throughout the present application, the term “capacitor” denotes an electric component that stores electrical energy by accumulating electric charges on two closely spaced apart electrically conductive plates that are insulated from each other by a capacitor dielectric layer.

Throughout the present application, the term “inductor-capacitor circuit or L-C circuit” denotes an electronic device that includes an inductor (L) and a capacitor (C) connected together. The L-C circuit can oscillate, i.e., it can exchange energy between magnetic fields in the inductor and electric fields in the capacitor. L-C circuits have frequency variability and sensing capabilities.

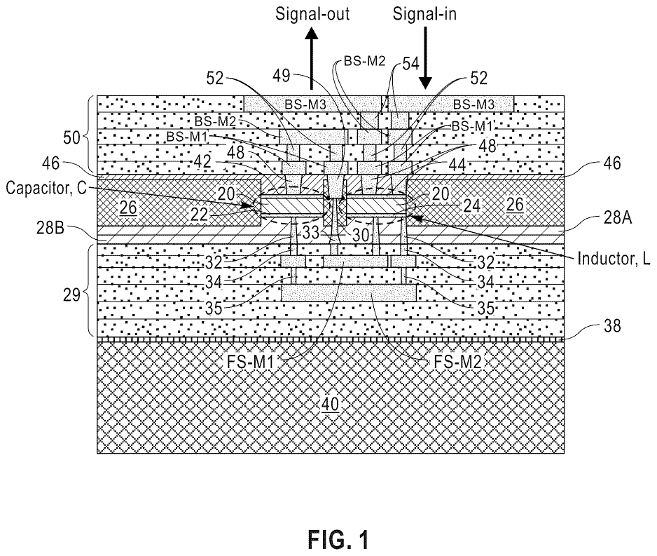

In the present application, a semiconductor device as illustrated in FIG. 1 is provided that includes an L-C circuit. The L-C circuit of the present application includes two inductors (see, for example, the circle region of FIG. 1 labeled as inductor, L that includes first inductor 24 and second inductor 44 which are vertically stacked and spaced apart by a capacitor dielectric layer 20) and a single capacitor (see, for example, the circle region of FIG. 1 labeled as capacitor, C, that includes first capacitor plate 22, capacitor dielectric layer 20 and second capacitor plate 42) that are present at a FEOL level 26. In accordance with the present application, the FEOL level 26 includes at least one semiconductor device present therein.

The L-C circuit of the present application further includes a first L-C circuit wiring portion (i.e., frontside metal vias 34, first level frontside metal lines, FS-M1, frontside interconnect metal via structures 35 and second level frontside metal lines, FS-MS2) located in frontside BEOL structure 29, and a second L-C circuit wiring portion (i.e., first level backside metal lines, BS-M1, first backside metal vias 52, second level backside metal lines, BS-M2, second backside vias 54, and third level backside metal lines, BS-M3) located in backside BEOL structure 50. In the present application, the backside BEOL structure 50 is configured to deliver power to the semiconductor devices that are present in the FEOL level 26.

In accordance with the present application, and as is further illustrated in FIG. 1, the first L-C circuit wiring portion and the second L-C circuit wiring portion are interconnected to each other at, and through, the FEOL level 26. In the present application and as further illustrated in FIG. 1, the interconnection of the first L-C circuit wiring portion and the second L-C circuit wiring portion can include a frontside device contact level and a backside device contact level. The frontside device contact level, which is positioned between the FEOL level 26 and the frontside BEOL structure 29, includes second frontside ILD layer 28B, frontside device contact via structures 32, frontside power via contact structure 33, frontside device contact via structures 32 and frontside power via contact structure 33 embedded in first frontside ILD layer 28A.

The backside device contact level, which is positioned between the FEOL level 26 and the backside BEOL structure 50, includes backside device contact via structures 48 and backside power via contact structure 49 embedded in first backside ILD layer 46.

In accordance with the present application and as is further illustrated in FIG. 1, the L-C circuit further includes power via structure 30 located in the FEOL level 26 that is located between the highlighted area including the capacitor, C, and the highlighted area including the inductors, L. Notably, the power via structure 30 passes through the FEOL level 26 that is located between the highlighted area including the capacitor, C, (i.e., capacitance device area) and the highlighted area including the inductors, L, (i.e., inductor device area) and is electrically connected to the second L-C circuit wiring portion by backside power via contact structure 49 and to the first L-C circuit wiring portion by frontside power via contact structure 33.

The L-C circuit of the present application which includes two inductors (i.e., first inductor 24 and second inductor 44) and a capacitor (i.e., first capacitor plate 22, capacitor dielectric layer 20 and second capacitor plate 42) can be used to observe shifts in resonant frequency and the L-C circuit can transmit vital data about physical parameters and potential failure modes ensuring stable and sustained operations of the semiconductor devices in the FEOL level 26. Notably, the L-C circuit of the present application as illustrated in FIG. 1 can serve as a monitoring system in the semiconductor device which can be used to detect temperature, strain and humidity at the FEOL level 26. The L-C circuit of the present application as illustrated in FIG. 1 can be used to further detect failure modes such as, for example, defects in dielectric materials, and/or Cu electromigration, at the FEOL level 26.

In some embodiments of the present application, the frontside BEOL structure 29 is attached to carrier wafer 40 by means of bonding dielectric layer 38. In other embodiments, no carrier wafer 40 or bonding dielectric layer 38 is present.

As is illustrated in FIG. 1, a signal (identified as Signal-in) can be introduced into a portion of the second L-C circuit wiring portion that is electrically connected to the second inductor 44. As is further illustrated, the signal (identified as Signal-out) can exist the L-C circuit through another portion of the second L-C circuit wiring portion that is electrically connected to the second inductor 44. The L-C circuit can oscillate, i.e., it can exchange energy between magnetic fields in the inductor and electric fields in the capacitor. L-C circuits have frequency variability and sensing capabilities. The natural or resonant frequency (f0) at which this occurs is determined by the values of L and C, following the relation: f0=1/(2π√LC).

Frequency shifts from resonant frequency of an L-C circuit is caused by change in capacitance in response to alterations in the dielectric environment and indicates alterations in environmental or operational conditions at placement of L-C circuit within the semiconductor build.

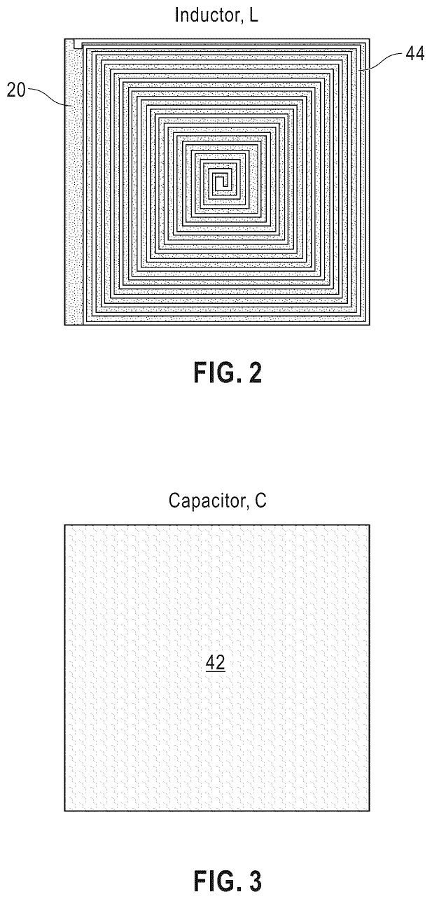

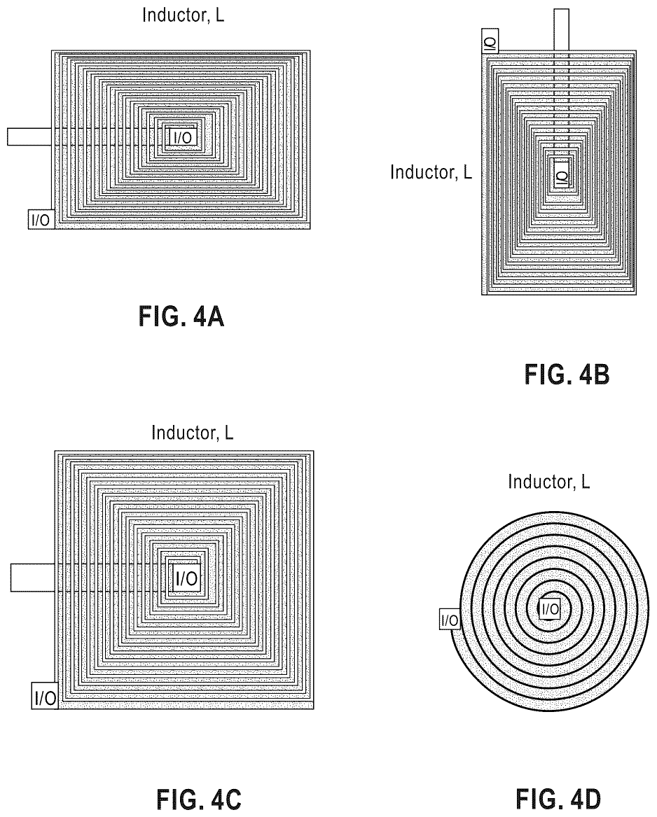

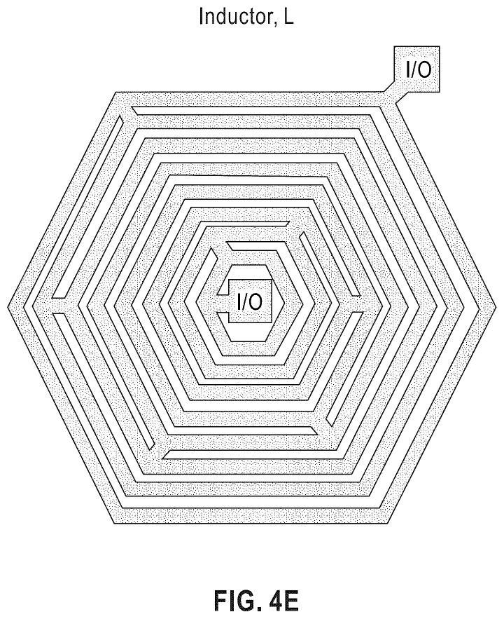

On of the highlighted areas of the exemplary semiconductor device of FIG. 1 is an inductor device area that includes the first inductor 24 and the second inductor 44. The inductor device area is shown in FIG. 2. Notably, FIG. 2 shows a top down view of the second inductor 44 illustrated in FIG. 1. As is illustrated in FIG. 2, the second inductor 44 is configured as a coil; the first inductor 24 is also configured as a coil. The first inductor 24 and the second inductor 44 can have various shapes as will be described in greater detail herein below with respect to the discussion of FIGS. 4A-4E. The first inductor 24 and the second inductor 44 are planar structures and are spaced apart by capacitor dielectric layer 20 as is illustrated in FIG. 1. The first inductor 24 and second inductor 44 can oscillate and generate magnetic fields when a voltage is applied thereto. Magnetic coupling can occur between the first inductor 24 and the second inductor 44.

Another of the highlighted areas of the exemplary semiconductor device of FIG. 1 is a capacitor device area the includes the capacitor of the present application. The capacitor device area is shown in FIG. 3. Notably FIG. 3 shows a top down view of the second capacitor plate 42 illustrated in FIG. 1; the first capacitor plate 22 typically, but not necessarily always, has a same shape as the second capacitor plate 42. Notably, the first capacitor plate 22 and second capacitor plate 42 can have a shape of a circle, rectangle or square. The first capacitor plate 22 and second capacitor plate 42 are planar structures that are spaced apart by capacitor dielectric layer 20. The capacitor can oscillate and generate an electrical field when a voltage is applied thereto.

Various inductor shapes that can be employed as the first inductor 24 and second inductor 44 illustrated in the exemplary semiconductor device shown in FIG. 1 are shown in FIGS. 4A-4E. Notably, FIGS. 4A and 4B illustrate inductors having a rectangular shape, FIG. 4C illustrates an inductor having a square shape, FIG. 4D illustrates an inductor having a spiral shape, and FIG. 4E illustrates an inductor having a hexagonal shape. Other inductor shapes are possible and can be used as the shape of the first inductor 24 and the second inductor 44 mentioned above. In some embodiments, the shape of the first inductor 24 is the same as the shape of the second inductor 44. In other embodiments, the shape of the first inductor 24 is different from the shape of the second inductor 44. The different shapes allow for design and optimization of inductance (L) of the L-C circuit, depending on the nature of application. In each of FIGS. 4A-4E, the input/out (I/O) regions are illustrated.

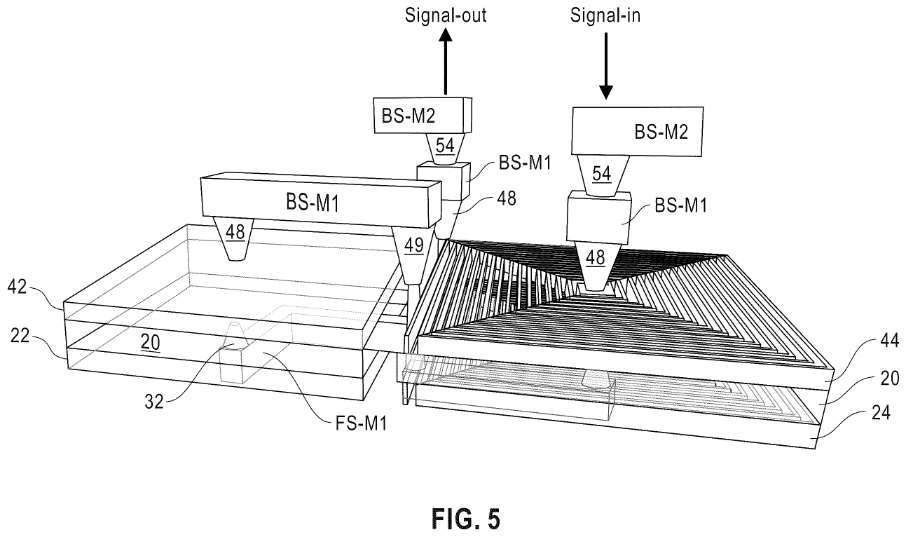

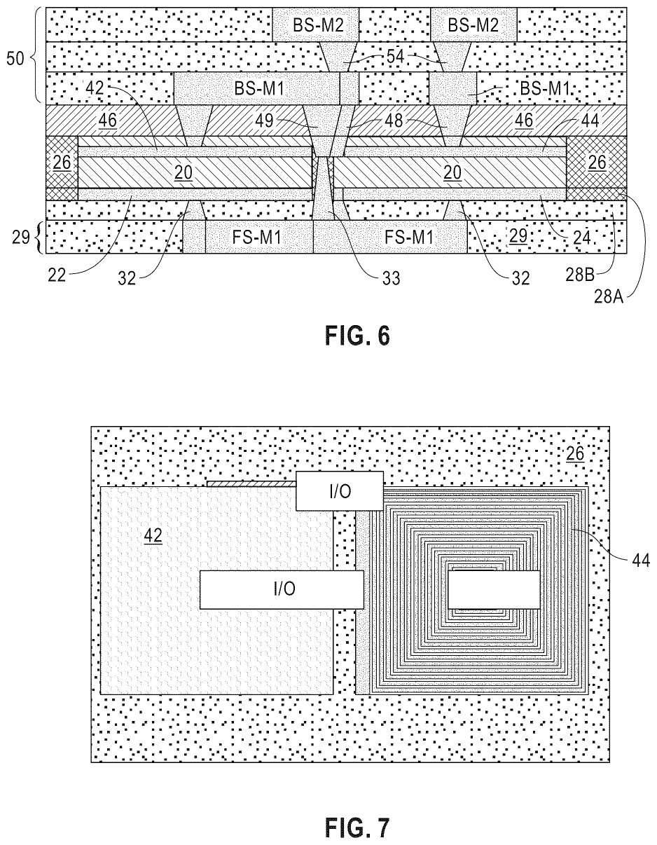

3D illustrations of the exemplary semiconductor device illustrated in FIG. 1 are shown in FIGS. 5 and 6. Notably, FIG. 5 is a 3D illustration highlighting the capacitor device area and the inductor device area as well as the second wiring portion of the L-C circuit that is included in the backside BEOL structure 50. While FIG. 6 is a 3D illustration highlighting the capacitor device area and the inductor device area, the first wiring portion that is included in the frontside BEOL structure 29 and the second wiring portion of the L-C circuit that is included in the backside BEOL structure 50. FIG. 6 also shows the frontside device contact level and the backside device contact level of the semiconductor device illustrated in FIG. 1.

FIG. 7 is an illustration highlighting the capacitor device area and the inductor device area of the L-C circuit illustrated in FIG. 1. Notably, FIG. 7 shows the second capacitor plate 42 and the second inductor 44 of the L-C circuit of the present application. Also illustrated in FIG. 7, is the FEOL level 26 and the I/O regions of the L-C-circuit of the present application.

Notably, FIG. 1 illustrates a semiconductor device in accordance with an embodiment of the present application, the device including FEOL level 26 having frontside BEOL structure 29 located on a frontside side of the FEOL level 26 and backside BEOL structure 50 located on a backside of the FEOL level 26; and an inductor-capacitor (L-C) circuit including first inductor 24, second inductor 44 and a capacitor (i.e., first capacitor plate 22, capacitor dielectric layer 20 and second capacitor plate 42) present at the FEOL level 26, a first L-C circuit wiring portion (as described above) located in the frontside BEOL structure 29, and a second L-C circuit wiring portion (as described above) located in the backside BEOL structure. 50. In accordance with the present application, the first L-C circuit wiring portion and the second L-C circuit wiring portion are interconnected to each other at, and through, the FEOL level 26.

In another embodiment, FIG. 1 discloses a semiconductor device that includes FEOL level 26 having frontside BEOL structure 29 located on a frontside side of the FEOL level 26 and backside BEOL structure 50 located on a backside of the FEOL level 26; and a monitor system. The monitor system is configured to detect environmental changes such as, for example, temperature, strain and humidity at the FEOL level 26, and it can further detect failure modes such as, for example, defects in dielectric materials, and/or Cu electromigration, at the FEOL level 26. The monitor system includes first inductor 24, second inductor 44 and a capacitor (i.e., first capacitor plate 22, capacitor dielectric layer 20 and second capacitor plate 42) present at the FEOL level 26, a first L-C circuit wiring portion (as described above) located in the frontside BEOL structure 29, and a second L-C circuit wiring portion (as described above) located in the backside BEOL structure. 50. In accordance with the present application, the first L-C circuit wiring portion and the second L-C circuit wiring portion are interconnected to each other at, and through, the FEOL level 26.

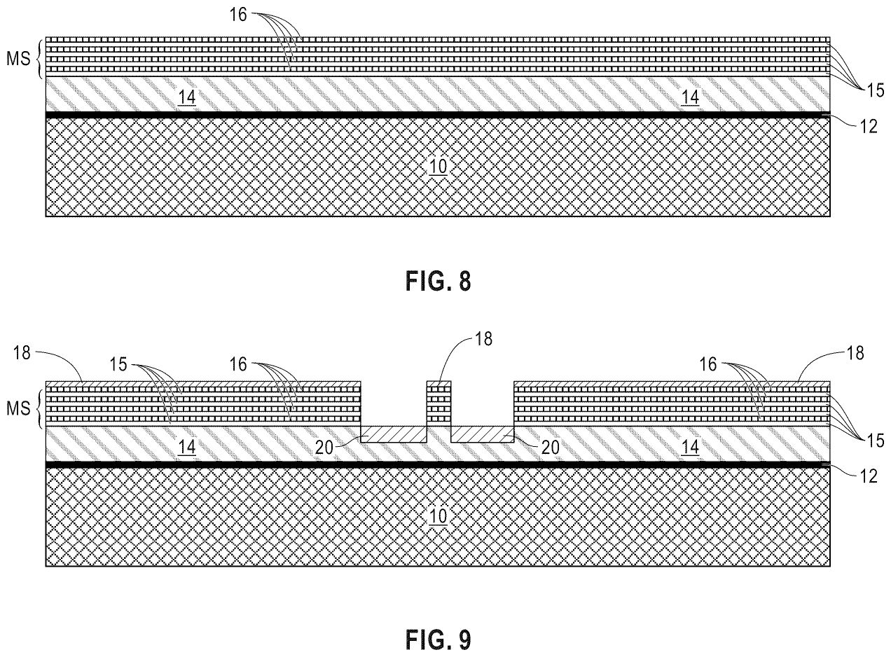

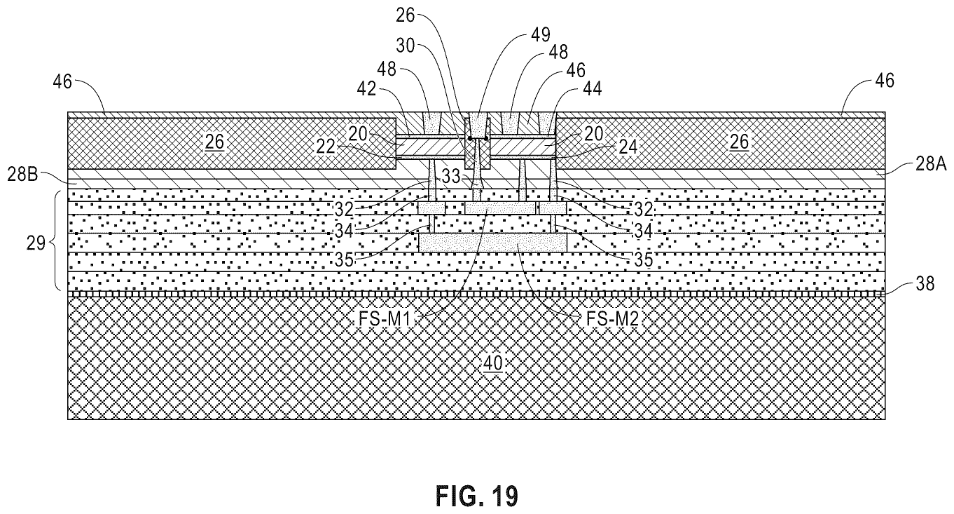

The method (i.e., processing flow) that can be used in forming an exemplary semiconductor device as illustrated in FIG. 1 will now be described in detail with reference to FIGS. 8-19; the method illustrated in FIGS. 8-19 would need to include further backside processing as disclosed subsequently herein to the structure illustrated in FIG. 19 to provide the semiconductor device illustrated in FIG. 1. Notably, FIG. 8 illustrates an initial structure that can be used in providing the exemplary semiconductor device illustrated in FIG. 1. The initial structure illustrated in FIG. 8 includes a material stack, MS, of alternating layers of sacrificial semiconductor material layers 15 and semiconductor channel material layers 16 located on a surface of a substrate.

The semiconductor substrate includes at least a semiconductor device layer 14. The semiconductor device layer 14 is an uppermost portion of the substrate in which at least one semiconductor device such as, for example, a transistor, will be subsequently formed thereon. The substrate can also include a semiconductor base layer 10 and/or an etch stop layer 12. In one example and as illustrated in FIG. 8, the substrate can include, from bottom to top, semiconductor base layer 10, etch stop layer 12 and semiconductor device layer 14. The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Each sacrificial semiconductor material layer 15 present in the material stack, MS, is composed of a fourth semiconductor material, while each semiconductor channel material layer 16 present in the material stack, MS, is composed of a fifth semiconductor material that is compositionally different from the fourth semiconductor material. The fourth semiconductor material that provides each sacrificial semiconductor material layer 15 is compositionally different from the second semiconductor material that provides the semiconductor device layer 14. The fifth semiconductor material that provides each semiconductor channel material layer 16 can be compositionally the same as, or compositionally different from, the second semiconductor material that provides the semiconductor device layer 14. In some embodiments, the fifth semiconductor material that provides each semiconductor channel material layer 16 can be used to provide high channel mobility for NFET devices. In other embodiments, the fifth semiconductor material that provides each semiconductor channel material layer 16 can be used to provide high channel mobility for PFET devices. In some embodiments, the semiconductor device layer 14 and each semiconductor channel material layer 16 are composed of Si, while each sacrificial semiconductor material layer 15 is composed of a SiGe alloy.

The number of sacrificial semiconductor material layers 15 and the number of semiconductor channel material layers 16 present in the material stack, MS, may vary and are not limited to the embodiment illustrated in FIG. 8 in which the material stack, MS, includes “n’ number of semiconductor channel material layers 16, and “n” number of sacrificial semiconductor material layers 15, where n is at least 2. In some embodiments not illustrated, the material stack, MS, can include “n” number of semiconductor channel material layers 16 and “n+1” number of sacrificial semiconductor material layers 15, where n is at least 2. In such embodiments, each semiconductor channel material layer 16 would be located between a bottom sacrificial semiconductor material layer and a top sacrificial semiconductor material layer.

The material stack, MS, is a patterned material stack that can be formed by first depositing, in an alternating manner, sacrificial semiconductor material layers 15 and semiconductor channel material layers 16, and then patterning the as-deposited stack of alternating layers of sacrificial semiconductor material layers 15 and semiconductor channel material layers 16. The depositing of the sacrificial semiconductor material layers 15 and semiconductor channel material layers 16 can include for example, chemical vapor deposition (CVD), plasma enhanced chemical vapor deposition (PECVD), and/or epitaxial growth.

Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

The patterning of the as-deposited stack includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned. The transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material.

The material stack, MS, illustrated in FIG. 8 is used in embodiments in which nanosheets transistors are to be formed on the semiconductor device layer 14. The material stack, MS, can be omitted in embodiments in which nanosheet transistors are not being formed.

Next, and as illustrated in FIG. 9, a pair of openings are formed into semiconductor device layer 14 of the substrate, and thereafter capacitor dielectric layer 20 is formed into the pair of openings. Although the present application describes and illustrates a single pair of openings that are filled with the capacitor dielectric layer 20, the present application is not limited to just a single pair of openings that are filled with the capacitor dielectric layer 20. Instead, a plurality of paired openings that are filled with the capacitor dielectric layer 20 can be formed into the semiconductor device layer 14.

The pair of openings can be formed by forming a patterned mask 18 on the material stack, MS; the patterned mask 18 includes a pattern of openings that will be used in forming the pair of openings. When the material stack, MS, is not present, the patterned mask 18 can be formed on a surface of the semiconductor device layer 14. The patterned mask 18 is composed of any well-known masking material or combination of well-known masking materials. For example, the patterned mask 18 can include a combination of a hard mask material (such as for example, silicon dioxide, silicon nitride and/or silicon nitride) and a photoresist material. In some embodiments the patterned mask 18 can be formed by deposition of the masking material, followed by lithographic patterning of the as-deposited masking material.

After forming the patterned mask 18, an etch such as, for example, RIE, can be used to transfer the openings in the patterned mask 18 into the material stack, MS, when the same is present, and then into the semiconductor device layer 14 forming the pair of openings in the semiconductor device layer 14. After forming the pair of openings, capacitor dielectric layer 20 is formed into each opening of the pair of openings. The capacitor dielectric layer 20 includes a capacitor dielectric such as, for example, silicon dioxide, a metal nitride (e.g., silicon nitride), or a material having a dielectric constant of greater than 4.0 such as, for example, TiO₂, Ta₂O₅, ZrO₂, including rare earth oxides such as Y₂O₃, La₂O₅, HfO₂, and their aluminates and silicates. All dielectric constants mentioned herein are measured in a vacuum unless otherwise noted. The filling of the pair of openings with capacitor dielectric layer 20 includes a deposition process such as, for example, CVD, PECVD or atomic layer deposition (ALD), and thereafter a planarization process such as, for example, chemical mechanical planarization (CMP) and a recces etch are used to remove any capacitor dielectric layer that is formed on top of the patterned mask 18 and outside of the pair of openings that are formed in the semiconductor device layer 14. The capacitor dielectric layer 20 has a topmost surface that is substantially coplanar with a topmost surface of the semiconductor device layer 14.

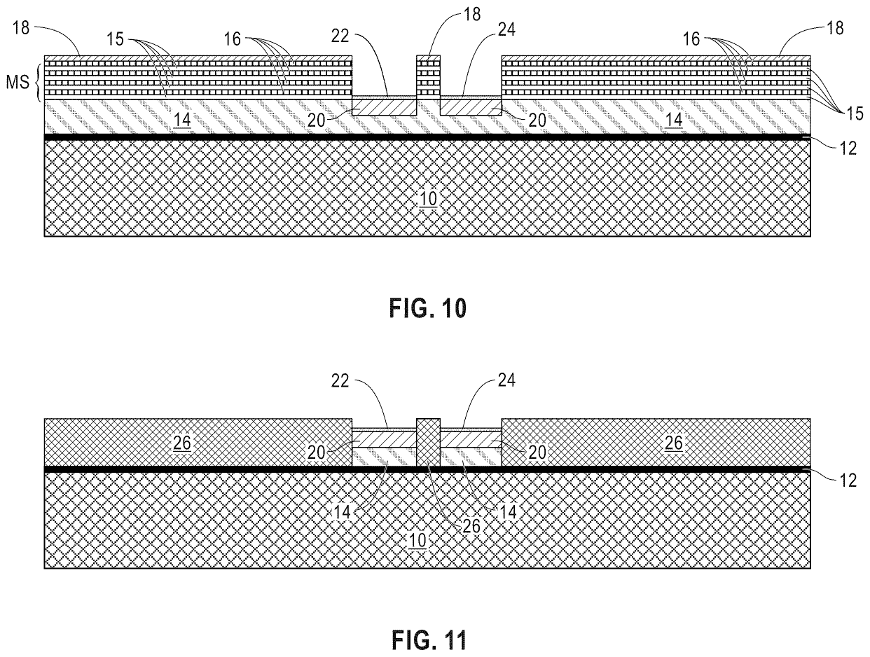

Next, and as illustrated in FIG. 10, first capacitor plate 22 is formed on the capacitor dielectric layer 20 in one of the openings of the pair of openings, and first inductor 24 is formed on the capacitor dielectric layer 20 in the other of the openings of the pair of openings. The first capacitor plate 22 and the first inductor 24 are composed of an electrically conductive metal or electrically conductive metal alloy. Illustrative examples of electrically conductive metals that can be used in providing the first capacitor plate 22 and the first inductor 24 include, but are not limited to, Cu, Cu, Al, Co, Ru, Mo, Os, Ir, or Rh. An illustrative electrically conductive alloy that can be used in providing the first capacitor plate 22 and the first inductor 24 includes, but is not limited to, a Cu—Al alloy. In some embodiments of the present application, the electrically conductive material that provides the first capacitor plate 22 can be compositionally the same as the electrically conductive material that provides the first inductor 24. In other embodiments of the present application, the electrically conductive material that provides the first capacitor plate 22 can be compositionally different from the electrically conductive material that provides the first inductor 24.

The forming of the first capacitor plate 22 and the first inductor 24 includes deposition of electrically conductive material as mentioned above. The deposition of the electrically conductive material can include, but is not limited to, CVD, PECVD, ALD, sputtering or plating. Following deposition of the electrically conductive material, a planarization process and a recess etch can be used in providing the first capacitor plate 22 and the first inductor 24. Note that the first capacitor plate 22 and the first inductor 24 are typically formed in separate processing steps using block mask technology. The first capacitor plate 22 and the first inductor 24 are planar. The first inductor 24 is configured as coil as illustrated in FIG. 2.

The patterned mask 18 is removed after forming the first capacitor plate 22 and the first inductor 24. The patterned mask 18 can be removed utilizing any material removal process that is selective in removing the masking material that provides the patterned mask 18.

After forming the first capacitor plate 22 and the first inductor 24 and removing the patterned mask 18, FEOL level 26, as illustrated in FIG. 11, is formed. The FEOL level 26 includes one or more semiconductor devices such as for example, transistors including nanosheet transistors located on semiconductor device layer 14. In the present application, the FEOL level 26 includes these semiconductor devices and the semiconductor device layer 14; the semiconductor devices and the semiconductor device layer 14 are not separately shown but are intended to be located in the FEOL level 26. The one or more semiconductor devices can be formed utilizing techniques well known in the art. During the formation of the one or more semiconductor devices, a block mask is formed over the first capacitor plate 22 and the first inductor 24. In regard to nanosheet transistors, conventional nanosheet processing steps which are also well known to one skilled in the art can be used to form nanosheets transistors. The nanosheet processing steps typically include the formation of a nanosheet stack of alternating sacrificial semiconductor channel material nanosheets (which are derived from the sacrificial semiconductor material layers 15 of the material stack, MS) and semiconductor channel material nanosheets (which are derived from the semiconductor channel material layers 16 of the material stack, MS) utilizing a sacrificial gate structure as an etch mask, recessing each sacrificial semiconductor material nanosheet, forming an inner spacer adjacent to each recessed sacrificial semiconductor material nanosheet, revealing the nanosheet stack by removing the sacrificial gate structure, releasing each of the semiconductor channel material nanosheets by removing each sacrificial semiconductor channel material nanosheet, and forming a gate structure including a gate dielectric and a gate electrode around a suspended portion of each semiconductor channel material nanosheets of the vertical stack of spaced apart semiconductor channel material nanosheets. Note that a portion of the FEOL level 26 is formed between the capacitor device area that now includes the capacitor dielectric layer 20/first capacitor plate 22, and the inductor device area that includes the capacitor dielectric layer 20/first inductor 24.

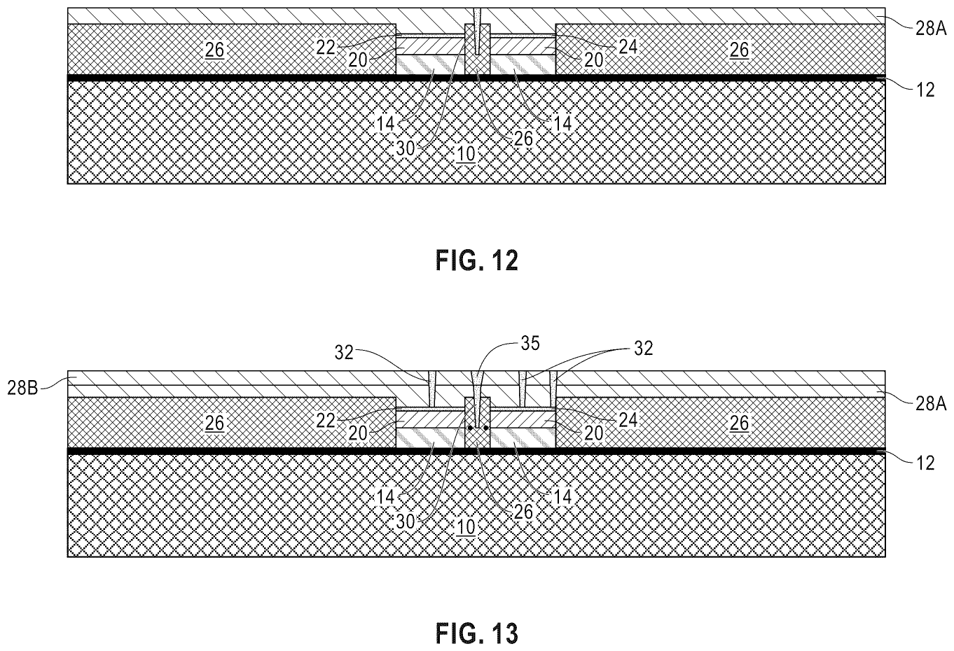

After forming the FEOL level 26 and as is illustrated in FIG. 12, first frontside ILD layer 28A is formed, and thereafter a power via structure 30 is formed in the first frontside ILD layer 28A and within a portion of the FEOL level 26 that is located between the pair of openings. The first frontside ILD layer 28A is formed on a topmost surface of the FEOL level 26, a topmost surface of the first capacitor plate 22 and a topmost surface of first inductor 24. The first frontside ILD layer 28A is composed of an ILD material such as, but not limited, to silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The first frontside ILD layer 28A can be formed by a deposition process such as, for example, CVD, PECVD or spin-on coating. In some embodiments, a planarization process can follow the deposition of the ILD material that provides the first frontside ILD layer 28A.

The power via structure 30 is composed of an electrically conductive metal and/or an electrically conductive metal alloy as mentioned above. The power via structure 30 can be formed by a metallization process which includes forming a power via opening into the first frontside ILD layer 28A and into a portion of the FEOL level 26 that is located between the pair of openings and then filling (by deposition, followed by planarization) the power via opening with an electrically conductive material.

After forming the power via structure 30 and as illustrated in FIG. 13, a second frontside ILD layer 28B is formed, and thereafter frontside device contact via structures 32 and a frontside power via contact structure 33 are formed. Collectively, the first frontside ILD layer 28A, the second frontside ILD layer 28B, the frontside device contact via structures 32, the frontside power via contact structure 33, the frontside device contact via structures 32 and the frontside power via contact structure 33 can be referred to as a frontside device contact level.

The second frontside ILD layer 28B is formed on top of the first frontside ILD layer 28A and on top of the power via structure 30. The second frontside ILD layer 28B can include an ILD material as mentioned above for the first frontside ILD layer 28A. The composition of the ILD material that provides the second frontside ILD layer 28B can be compositionally the same as, or compositionally different from, the ILD material that provides the first frontside ILD layer 28A. The second frontside ILD layer 28B can be formed utilizing a deposition process as mentioned above in forming the first frontside ILD layer 28A.

The frontside device contact via structures 32 and the frontside power via contact structure 33 are composed of at least a contact conductor material. The contact conductor material can include, for example, a conductive metal such as, for example, W, Cu, Al, Co, Ru, Mo, Os, Ir, Rh, or an alloy thereof. The frontside device contact via structures 32 and the frontside power via contact structure 33 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The frontside device contact via structures 32 and the frontside power via contact structure 33 can be formed utilizing processing techniques that are well known to those skilled in the art such, as for example, a metallization process.

As is illustrated, one of the frontside device contact via structures 32 that is formed is in direct contact with the first capacitor plate 22, while at least one other frontside device contact via structures 32 that is formed is in direct contact with the first inductor 24. The frontside power via contact structure 33 is in direct contact with the power via structure 30.

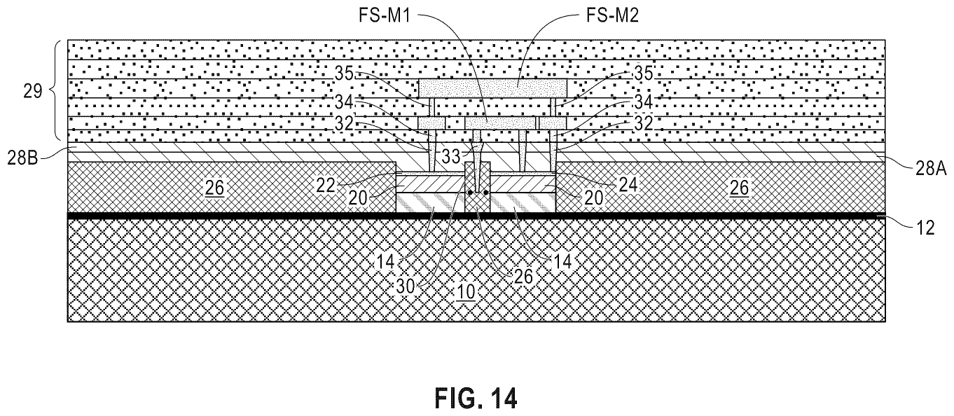

Next, and as illustrated in FIG. 14, additional frontside ILD layers are formed that include frontside metal vias 34, first level frontside metal lines, FS-M1, frontside interconnect metal via structures 35 and second level frontside metal lines, FS-MS2, embedded in the additional frontside ILD layers. In the present application, some of the frontside metal vias 34 are used to interconnect some of the first level frontside metal lines, FS-M1 to frontside device contact via structures 32, while at least one other frontside metal via 34 is used to interconnect one of the first level frontside metal lines, FS-M1, to frontside power via contact structure 33. The frontside interconnect metal via structures 35 are used to interconnect the second level frontside metal lines, FS-MS2, to the first level frontside metal lines, FS-MS1. Collectively, the additional frontside ILD layers form a dielectric region of a frontside BEOL structure 29 that has a first L-C circuit wiring portion embedded therein, The first L-C circuit wiring portion includes frontside metal vias 34, first level frontside metal lines, FS-M1, frontside interconnect metal via structures 35 and second level frontside metal lines, FS-MS2.

Each additional frontside ILD layer that provides the additional frontside ILD layers is composed of an ILD material as mentioned above for the first frontside ILD layer 28A. Each additional frontside ILD layer that provides the additional frontside ILD layers can be formed utilizing a deposition process as mentioned above in forming the first frontside ILD layer 28A.

The first L-C circuit wiring portion including the frontside metal vias 34, first level frontside metal lines, FS-M1, frontside interconnect metal via structures 35 and second level frontside metal lines, FS-MS2 can be composed of an electrically conductive metal or an electrically conductive metal alloy both as exemplified above. Typically, the first L-C circuit wiring portion including frontside metal vias 34, first level frontside metal lines, FS-M1, frontside interconnect metal via structures 35 and second level frontside metal lines, FS-MS2 can be formed utilizing a damascene process which includes forming an opening (via or line opening) in one of the as-deposited additional frontside ILD layer, and then filling (by deposition and planarization) the opening with an electrically conductive material. In some embodiments, a subtractive etching process can be used in which a particularly wiring structure (e.g., frontside metal via 34) is formed by deposition and patterning, and then one of the additional frontside ILD layers is formed by deposition and planarization.

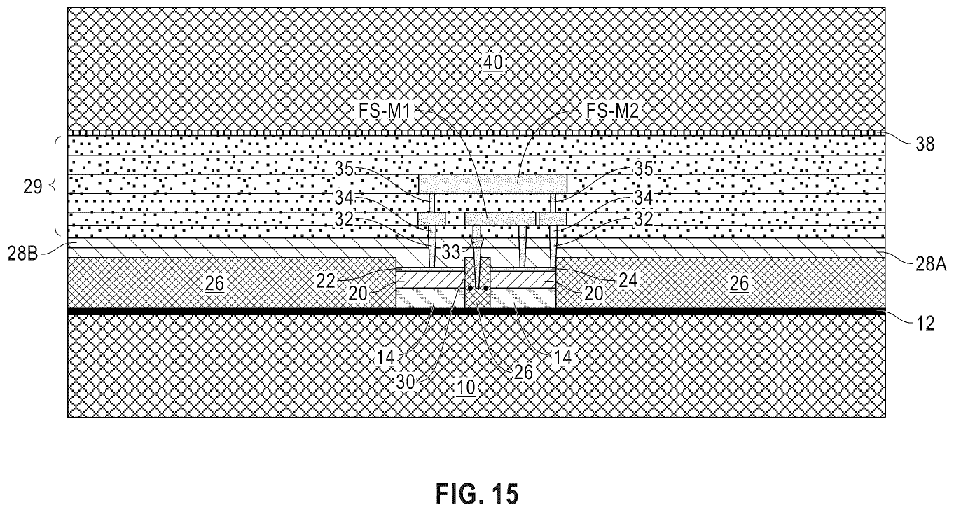

Next, and as illustrated in FIG. 15, carrier wafer 40 is bonded to a topmost additional frontside ILD layer of the additional frontside ILD layers utilizing a bonding dielectric layer 38. Carrier wafer 40 can include a semiconductor material as exemplified above. Bonding dielectric layer 38 includes a bonding dielectric material such as, but are not limited to, tetraethyl orthosilicate (TEOS), SiO₂, silicon carbon nitride (SiCN) and/or carbon-doped silicon oxide (SiCOH). In some embodiments of the present application, an entirety of the bonding dielectric layer 38 is formed (by a deposition process) onto either the carrier wafer 40 or the topmost additional frontside ILD layer of the additional frontside ILD layers, and such a structure is brought into contact with the other of the carrier wafer 40 or the topmost additional frontside ILD layer of the additional frontside ILD layers not including the bonding dielectric layer 38 and thereafter a wafer-to-wafer bonding process is performed. In other embodiments, a first portion of the bonding dielectric layer 38 is formed (by a deposition process) onto the carrier wafer 40 and a second portion of the bonding dielectric layer 38 is formed (by deposition) on the topmost additional frontside ILD layer of the additional frontside ILD layers, and the two bonding dielectric layer portions are brought into contact with each other, and then a wafer-to-wafer bonding process can be performed. The wafer-to-wafer bonding process can include a heating step in which the intimately contacted structures are heated from room temperature (i.e., 20° C.-25° C.) up to 450° C.; temperatures greater than 450° C. can also be used in the present application. The bonding process is typically performed in an inert ambient such as, for example, He, Ar, Ne or mixtures thereof.

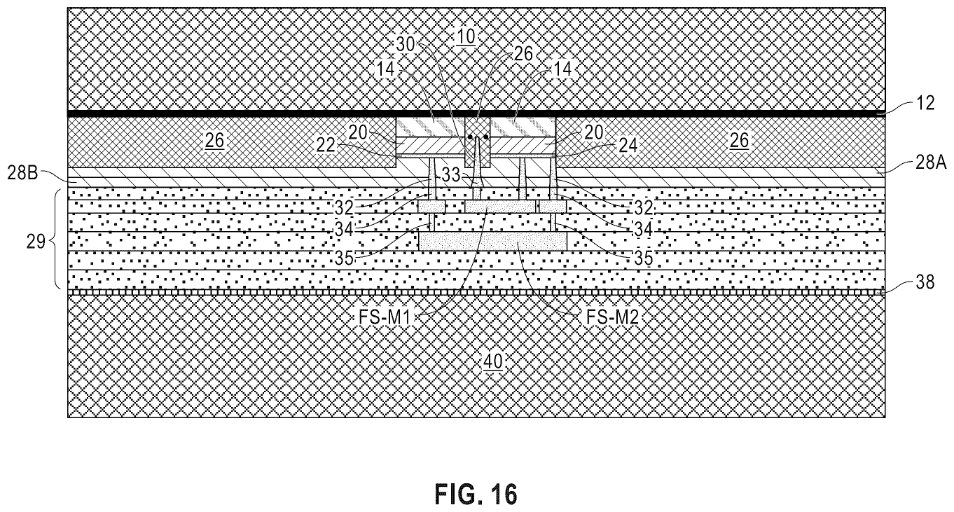

Next, and illustrated in FIG. 16, the structure illustrated in FIG. 15 is flipping 180° to physically expose semiconductor base layer 10 of the substrate. Flipping can be performed by hand or by utilizing a mechanical means such as, for example, a robot arm.

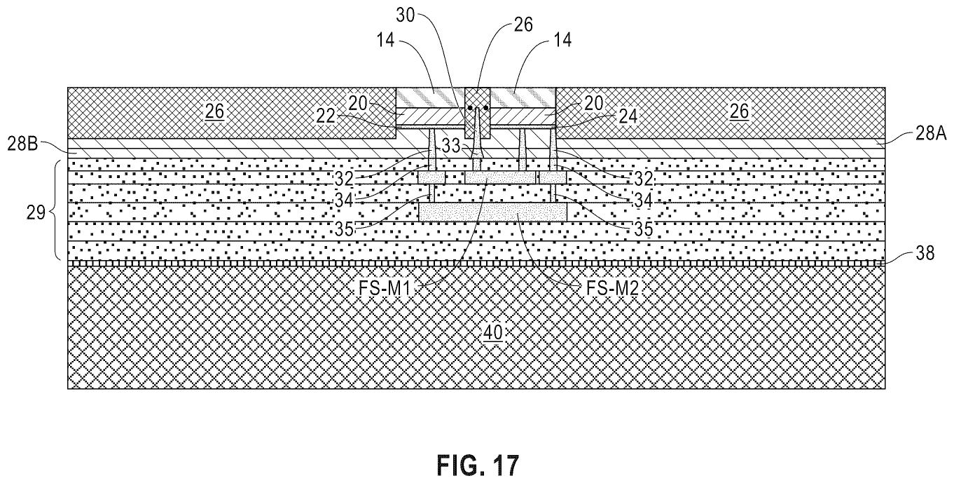

After flipping the structure, the semiconductor base layer 10 and the etch stop layer 12 of the substrate can be removed as illustrated in FIG. 17 to physically expose a backside of the FEOL level 26 and the semiconductor device layer 14 that is located in contact with the capacitor dielectric layer 20 (i.e., the semiconductor device layer 14 that is still present in the capacitor device area and the inductor device area). The removal of either the semiconductor base layer 10 or the etch stop layer 12 can be omitted when either the semiconductor base layer 10 or the etch stop layer 12 is not present in the substrate. When present, the semiconductor base layer 10 is removed utilizing a material removal process that is selective in removing the semiconductor material that provides the semiconductor base layer 10. In the illustrated embodiment, the removal of the semiconductor base layer 10 reveals the etch stop layer 12 of the substrate. When present, the etch stop layer 12 is removed utilizing a material removal process that is selective in removing the material that provides the etch stop layer 12.

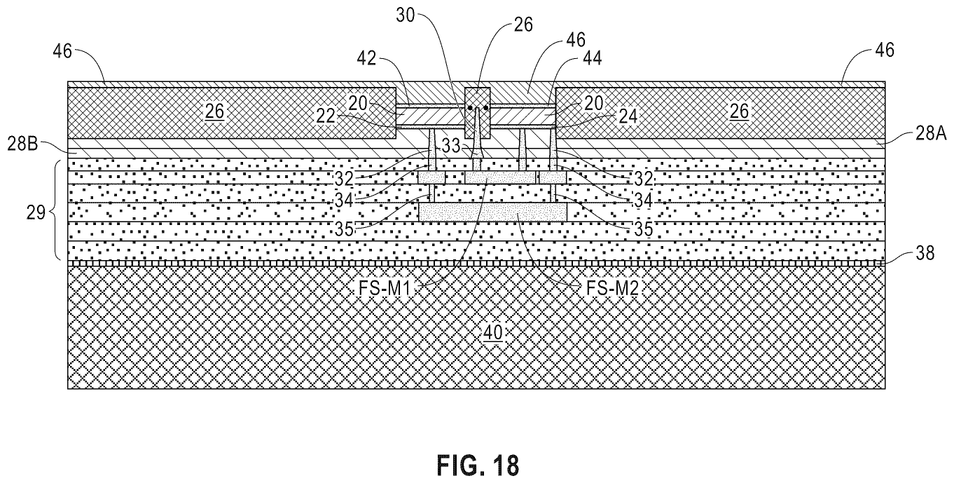

Next, and as is illustrated in FIG. 18, the capacitor dielectric layer 20 present in the pair of openings (i.e., in the capacitor device area and the inductor device area) is physically exposed by removing the semiconductor device layer 14. The semiconductor device layer 14 can be removed by utilizing a material removal process that is selective in removing the semiconductor material that provides the semiconductor device layer. It is noted that the removal of the semiconductor device layer 14 also removes the semiconductor device layer 14 from the FEOL level 26. After removing the semiconductor device layer 14 and as further illustrated in FIG. 18, a second capacitor plate 42 is formed on the capacitor dielectric layer 20 in one of the openings of the pair of openings, and a second inductor 44 is formed on the capacitor dielectric layer 20 in the other of the openings of the pair of openings.

The second capacitor plate 42 and the second inductor 44 are composed of an electrically conductive metal or electrically conductive metal alloy as mentioned above for the first capacitor plate 22 and first inductor 24. In some embodiments of the present application, the electrically conductive material that provides the second capacitor plate 42 can be composed of a compositionally same electrically conductive material as that which provides the second inductor 44. In other embodiments of the present application, the electrically conductive material that provides the second capacitor plate 42 can be compositionally different from the electrically conductive material that provides second inductor 44. In the present application, the first capacitor plate 22 and the second capacitor plate 42 can be composed of a compositionally same or compositionally different electrically conductive materials. In the present application, the first inductor 24 and the second inductor 44 can be composed of a compositionally same or compositionally different electrically conductive materials.

The forming of the second capacitor plate 42 and the second inductor 44 includes deposition of electrically conductive material as mentioned above. The deposition of the electrically conductive material can include, but is not limited to, CVD, PECVD, ALD, sputtering or plating. Following deposition of the electrically conductive material, a planarization process and a recess etch can be used in providing the second capacitor plate 42 and the second inductor 44. Note that the second capacitor plate 42 and the second inductor 44 are typically formed in separate processing steps using block mask technology. The second capacitor plate 42 and the second inductor 44 are planar. The second inductor 44 is configured as a coil as is illustrated in FIG. 2.

After forming the second capacitor plate 42 and the second inductor 44 and as further illustrated in FIG. 18, first backside ILD layer 46 is formed. The first backside ILD layer 46 is composed of an ILD material as mentioned above for the first frontside ILD layer 28A. The first backside ILD layer 46 can be formed by deposition of an ILD material. In some embodiments, a planarization process can follow the deposition of the ILD material to provide first backside ILD layer 46 as illustrated in FIG. 18.

Next, and as illustrated in FIG. 19, backside device contact via structures 48 and a backside power via contact structure 49 are formed in the first backside ILD layer 46. Collectively, the first backside ILD layer 46, the backside device contact via structures 48 and the backside power via contact structure 49 can be referred to as backside device contact level. The backside device contact via structures 48 and the backside power via contact structure 49 are composed of at least a contact conductor material as described above. Various contact liners as mentioned above can also be used in providing the backside device contact via structures 48 and the backside power via contact structure 49. As is illustrated one of the backside device contact via structures 48 that is formed is in direct contact with the second capacitor plate 42, while at least one other backside device contact via structure 48 that is formed is in direct contact with the second inductor 44. The backside power via contact structure 49 is in direct contact with the power via structure 30.

After forming the structure illustrated in FIG. 19, further backside process is performed to provide the exemplary semiconductor device illustrated in FIG. 1. Notably, additional backside ILD layers are formed that include first level backside metal lines, BS-M1, first backside metal vias 52, second level backside metal lines, BS-M2, second backside vias 54, and third level backside metal lines, BS-M3.

In the present application, some of the first level backside metal lines, BS-M1, are connected to the backside device contact via structures 48 and at least one first level backside metal lines, BS-M1 is connected to the backside power via contact structure 49. In the present application, each first backside metal via 52 is used to interconnect one of the second level backside metal lines, BS-M2 to one of the first level backside metal lines, BS-M1, and each second backside via 54 is used to interconnect one of the third level backside metal lines, BS-M3 to one of the second level backside metal lines, BS-M2 that is electrically connected to the second inductor 44.

Collectively, the additional backside ILD layers form a dielectric region of a backside BEOL structure 50 that has a second L-C circuit wiring portion embedded therein, The second L-C circuit wiring portion includes first level backside metal lines, BS-M1, first backside metal vias 52, second level backside metal lines, BS-M2, second backside vias 54, and third level backside metal lines, BS-M3.

Each additional frontside ILD layer that provides the additional backside ILD layers is composed of an ILD material as mentioned above for the first frontside ILD layer 28A. Each additional frontside ILD layer that provides the additional backside ILD layers can be formed utilizing a deposition process as mentioned above in forming the first frontside ILD layer 28A.

The second L-C circuit wiring portion including first level backside metal lines, BS-M1, first backside metal vias 52, second level backside metal lines, BS-M2, second backside vias 54, and third level backside metal lines, BS-M3, can be composed of an electrically conductive metal or an electrically conductive metal alloy both as exemplified above. The second L-C circuit wiring portion including first level backside metal lines, BS-M1, first backside metal vias 52, second level backside metal lines, BS-M2, second backside vias 54, and third level backside metal lines, BS-M3, can be formed utilizing a damascene process or a subtractive etch process as mentioned above

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a front-end-of-the-line (FEOL) level having a frontside back-of-the-line (BEOL) structure located on a frontside side of the FEOL level and a backside BEOL structure located a backside of the FEOL level; and
an inductor-capacitor (L-C) circuit comprising a first inductor, a second inductor and a capacitor present at the FEOL level, a first L-C circuit wiring portion located in the frontside BEOL structure, and a second L-C circuit wiring portion located in the backside BEOL structure, wherein the first L-C circuit wiring portion and the second L-C circuit wiring portion are interconnected to each other at, and through, the FEOL level.

2. The semiconductor device of claim 1, wherein the capacitor comprises a first capacitor plate electrically connected to the first L-C circuit wiring portion and a second capacitor plate electrically connected to the second L-C circuit wiring portion.

3. The semiconductor device of claim 1, wherein the first inductor is electrically connected to the first L-C circuit wiring portion and a second inductor is electrically connected to the second L-C circuit wiring portion.

4. The semiconductor device of claim 1, wherein the first inductor and the second inductor are vertically stacked and are spaced apart by a capacitor dielectric layer.

5. The semiconductor device of claim 1, wherein each of the first inductor and the second inductor is a planar structure.

6. The semiconductor device of claim 1, wherein each of the first inductor and the second inductor is a coil having a shape of a rectangle, a square, a spiral, or a hexagon.

7. The semiconductor device of claim 1, wherein the first L-C circuit wiring portion comprises frontside metal vias, first level frontside metal lines, frontside interconnect metal via structures and second level frontside metal lines.

8. The semiconductor device of claim 1, wherein the second L-C circuit wiring portion comprises first level backside metal lines, first backside metal vias, second level backside metal lines, second backside vias, and third level backside metal lines.

9. The semiconductor device of claim 1, wherein the first L-C circuit wiring portion and the second L-C circuit wiring portion are interconnected to each other at, and through, the FEOL level utilizing a frontside device contact level and a backside device contact level.

10. The semiconductor device of claim 9, wherein the frontside device contact level is located between the FEOL level and the frontside BEOL structure, and comprises a first frontside interlayer dielectric (ILD) layer, a second frontside ILD layer, frontside device contact via structures, a frontside power via contact via structure, frontside device contact via structures and a frontside power via contact via structure.

11. The semiconductor device of claim 10, wherein the backside device contact level is located between the FEOL level and the backside BEOL structure, and comprises a first backside ILD layer, backside device contact via structures and a backside power via contact via structure.

12. The semiconductor device of claim 1, further comprising a power via structure located in the FEOL level and positioned between a capacitor device area including the capacitor and an inductor device area including the first inductor and the second inductor, wherein the power via structure is electrically connected to the second L-C circuit wiring portion by a backside power via contact structure and to the first L-C circuit wiring portion by a frontside power via contact structure.

13. A semiconductor device comprising:
front-end-of-the-line (FEOL) level having a frontside back-of-the-line (BEOL) structure located on a frontside side of the FEOL level and a backside BEOL structure located on a backside of the FEOL level; and
a monitor system configured to detect environmental and detect failure modes at the FEOL level, the monitor system comprising a first inductor, a second inductor and a capacitor present at the FEOL level, a first L-C circuit wiring portion located in the frontside BEOL structure, and a second L-C circuit wiring portion located in the backside BEOL structure, wherein the first L-C circuit wiring portion and the second L-C circuit wiring portion are interconnected to each other at, and through, the FEOL level.

14. The semiconductor device of claim 13, wherein the capacitor comprises a first capacitor plate electrically connected to the first L-C circuit wiring portion and a second capacitor plate electrically connected to the second L-C circuit wiring portion.

15. The semiconductor device of claim 13, wherein the first inductor is electrically connected to the first L-C circuit wiring portion and the second inductor is electrically connected to the second L-C circuit wiring portion.

16. The semiconductor device of claim 13, wherein the first inductor and the second inductor are vertically stacked and are spaced apart by a capacitor dielectric layer.

17. The semiconductor device of claim 13, wherein each of the first inductor and the second inductor is a planar structure.

18. The semiconductor device of claim 13, wherein each of the first inductor and the second inductor is a coil having a shape of a rectangle, a square, a spiral, or a hexagon.

19. The semiconductor device of claim 13, further comprising a power via structure located in the FEOL level and positioned between a capacitor device area including the capacitor and an inductor device area including the first inductor and the second inductor, wherein the power via structure is electrically connected to the second L-C circuit wiring portion by a backside power via contact structure present in an backside device contact level and to the first L-C circuit wiring portion by a frontside power via contact structure present in a frontside device contact level.

20. The semiconductor device of claim 19, herein the backside device contact level is located between the FEOL level and the backside BEOL structure, and the frontside device contact level is located between the FEOL level and the backside BEOL structure.
